(19) United States
(12) Patent Application Publication
(10) Pub. No.: US 2006/0240280 A1
(43) Pub. Date: Oct. 26, 2006

(54) OLED anode modification layer

(75) Inventors: Liang-Sheng Liao, Rochester, NY (US); Kevin P. Klubek, West Henrietta, NY (US); Wojciech K. Slusarek, Rochester, NY (US)

Correspondence Address: Pamela R. Crocker;Eastman Kodak Company, Patent Legal Staff, 343 State Street, Rochester, NY, 14650-2201, US

(73) Assignee: Eastman Kodak Company

(21) Appl. No.: 11/111,367

(22) Filed: Apr. 21, 2005

(51) Int. Cl. H01L 51/54; H05B 33/12

(52) U.S. Cl. 428/690; 428/917; 313/504; 313/506; 257/E51.05; 257/E51.047; 257/40

(57) ABSTRACT

An OLED includes an anode formed over a substrate, wherein the anode is a non-oxygen-treated anode and an anode modification layer formed in direct contact with the anode, wherein the anode modification layer includes one or more organic materials, each having an electron-accepting property and a reduction potential greater than 0.0 V vs. a Saturated Calomel Electrode, and wherein the one or more organic materials provide more than 50% by mole ratio of the anode modification layer. The OLED also includes an organic electroluminescent unit formed over the anode modification layer, wherein the organic electroluminescent unit includes at least a hole-transporting layer and a light-emitting layer, and a cathode formed over the organic electroluminescent unit.

### CROSS REFERENCE TO RELATED APPLICATIONS

Reference is made to commonly assigned U.S. patent application Ser. No. ______ (Docket 89288) filed concurrently herewith by Liang-Sheng Liao et al., entitled “Contaminant-Scavenging Layer on OLED Anodes”, the disclosure of which is herein incorporated by reference.

### FIELD OF INVENTION

The present invention relates to simplifying the fabrication of an organic light-emitting device (OLED).

### BACKGROUND OF THE INVENTION

Multiple-layered organic light-emitting devices or organic electroluminescent (EL) devices, as first described by Tang in commonly assigned U.S. Pat. No. 4,356,429, are used as color pixel components in OLED displays and are also used as solid-state lighting sources. OLEDs are also useful for some other applications due to their low drive voltage, high luminance, wide viewing angle, fast signal response time, and simple fabrication process.

A typical OLED includes two electrodes and one organic EL unit disposed between the two electrodes. The organic EL unit commonly includes an organic hole-transporting layer (HTL), organic light-emitting layer (LEL), and an organic electron-transporting layer (ETL). One of the electrodes is the anode, which is capable of injecting positive charges (holes) into the HTL of the EL unit, and the other electrode is the cathode, which is capable of injecting negative charges (electrons) into the ETL of the EL unit. When the OLED is positively biased with certain electrical potential between the two electrodes, holes injected from the anode and electrons injected from the cathode can recombine and emit light from the LEL. Since at least one of the electrodes is optically transmissive, the emitted light can be seen through the transmissive electrode.

In an OLED fabrication process, an anode is typically formed on a substrate separately from the fabrication of the rest part of the OLED. For example, a commonly used transparent anode, indium-tin-oxide (ITO) or indium zinc-oxide (IZO) is formed and patterned on a transparent substrate or on a thin film transistor (TFT) backplane by ion sputtering technique. However, the as-prepared or clean ITO cannot be used as an effective anode because of its relatively low work function. The low work function anode will form a high barrier for holes to inject from the anode into the adjacent organic EL unit, resulting in high drive voltage and low operational lifetime. Therefore, the anode top surface typically needs to be modified. Several prior art, such as that reported by Mason et al. in Journal of Applied Physics 86(3), 1688 (1999), indicated that the work function of an anode, such as ITO, is related to the oxygen content on the surface, and increasing the oxygen content on the anode surface will increase the work function of the anode. Thus, an anode can be modified by an oxygen treatment, such as oxygen plasma treatment or ultraviolet excited ozone exposure (or UV ozone treatment).

However, oxygen treatments are difficult to provide precise oxygen content on anode surface because many factors, such as different initial anode surface conditions, deviations on physical position during oxygen treatment, and deviations on plasma intensity, can influence the process. As a result, the anode surface modification cannot be reproducible causing different work function on different anode surface. Moreover, the oxygen-rich anode surface is not stable. The oxygen on the surface will diffuse or electrically migrate into the adjacent organic layer causing a work function decrease on the anode surface and causing diffusion-related problems inside the organic layers.

An OLED fabricated on an oxygen-treated anode has improved EL performance comparing with that fabricated on an as-received anode. However, the improved EL performance is not effective enough for real applications. In order to further improve the EL performance, an anode with or without oxygen treatment can be modified by a layer over the anode surface, called anode buffer layer, before an organic EL unit is formed on its surface. This anode buffer layer in contact with the anode top surface, such as a thin oxide layer as disclosed in U.S. Pat. No. 6,351,067, and a plasma-deposited fluorocarbon polymers (denoted as CFₓ) as disclosed in U.S. Pat. No. 6,208,075, can enhance the luminous efficiency and the operational lifetime of OLED.

Since the anode buffer layer is typically a dielectric layer with high resistivity, if there is an anode buffer layer on the anode surface, the drive voltage of the OLED will be very sensitive to the thickness of the anode buffer layer. Thick anode buffer layer will cause very high drive voltage. Practically, it is very difficult to control the thickness of the anode buffer layer within the range of from 0.5 nm to about 5 nm for manufacturing. Moreover, since the anode buffer layer is typically formed at very high temperature (for example, higher than 800° C.), the fabrication method of the anode buffer layer is typically not compatible with that of the organic EL unit causing high manufacturing cost.

Therefore, it is clear that the aforementioned anode modification process, including oxygen treatment or depositing an anode buffer layer, is not feasible or convenient for manufacturing.

### SUMMARY OF THE INVENTION

It is therefore an object of the present invention to simplify the anode surface modification process for the fabrication of OLED.

It is another object of the present invention to reduce the manufacturing cost of OLED display.

It is yet another object of the present invention to improve the EL performance of the OLED.

These objects are achieved by an OLED comprising:

a) an anode formed over a substrate, wherein the anode is a non-oxygen-treated anode;

b) an anode modification layer formed in direct contact with the anode, wherein the anode modification layer includes one or more organic materials, each having an electron-accepting property and a reduction potential greater than 0.0 V vs. a Saturated Calomel Electrode, and wherein the one or more organic materials provide more than 50% by mole ratio of the anode modification layer;

c) an organic electroluminescent unit formed over the anode modification layer, wherein the organic electroluminescent unit includes at least a hole-transporting layer and a light-emitting layer; and

d) a cathode formed over the organic electroluminescent unit.

The present invention makes use of an anode modification layer in direct contact with a non-oxygen-treated anode surface to effectively oxidize the anode surface and form a low or non-barrier for holes to inject from the anode into the organic EL unit adjacent to the anode modification layer. It is an advantage of the present invention that the OLED with an anode modification layer can not only have a simple anode modification process but also have improved operational stability, which is very useful for making high quality device with low manufacturing cost.

### BRIEF DESCRIPTION OF THE DRAWINGS

FIG. 1 shows a cross-sectional view of a prior art OLED;

FIG. 2 shows a cross-sectional view of another prior art OLED;

FIG. 3 shows a cross-sectional view of yet anther prior art OLED;

FIG. 4 shows a cross-sectional view of one embodiment of an OLED prepared with an anode modification layer formed over a non-oxygen-treated anode in accordance with the present invention;

FIG. 5 shows a cross-sectional view of one embodiment of an organic electroluminescent unit including a hole-transporting layer, a light-emitting layer, and an electron-transporting layer in accordance with the present invention;

FIG. 6 shows a cross-sectional view of another embodiment of an organic electroluminescent unit including a hole-injecting layer, a hole-transporting layer, a light-emitting layer, and an electron-transporting layer in accordance with the present invention;

FIG. 7 shows a cross-sectional view of yet another embodiment of an organic electroluminescent unit including a hole-injecting layer, a hole-transporting layer, a light-emitting layer, an electron-transporting layer, and an electron-injecting layer in accordance with the present invention;

FIG. 8 shows a cross-sectional view of yet another embodiment of an organic electroluminescent unit including a hole-injecting layer, a light-emitting layer, and an electron-injecting layer in accordance with the present invention;

FIG. 9 is a graph showing the luminance vs. operational time of a group of OLEDs tested at room temperature and at 80 mA/cm²;

FIG. 10 is a graph showing the luminance vs. operational time of another group of OLEDs tested at room temperature and at 80 mA/cm²;

FIG. 11 is a graph showing the drive voltage vs. operational time of another group of OLEDs tested at room temperature and at 80 mA/cm²;

FIG. 12 is a graph showing the luminance vs. operational time of yet another group of OLEDs tested at room temperature and at 80 mA/cm²;

FIG. 13 is a graph showing the drive voltage vs. operational time of yet another group of OLEDs tested at room temperature and at 80 mA/cm²;

FIG. 14 is a graph showing the luminance vs. operational time of yet another group of OLEDs tested at 85° C. and at 80 mA/cm²; and

FIG. 15 is a graph showing the drive voltage vs. operational time of yet another group of OLEDs tested at 85° C. and at 80 mA/cm².

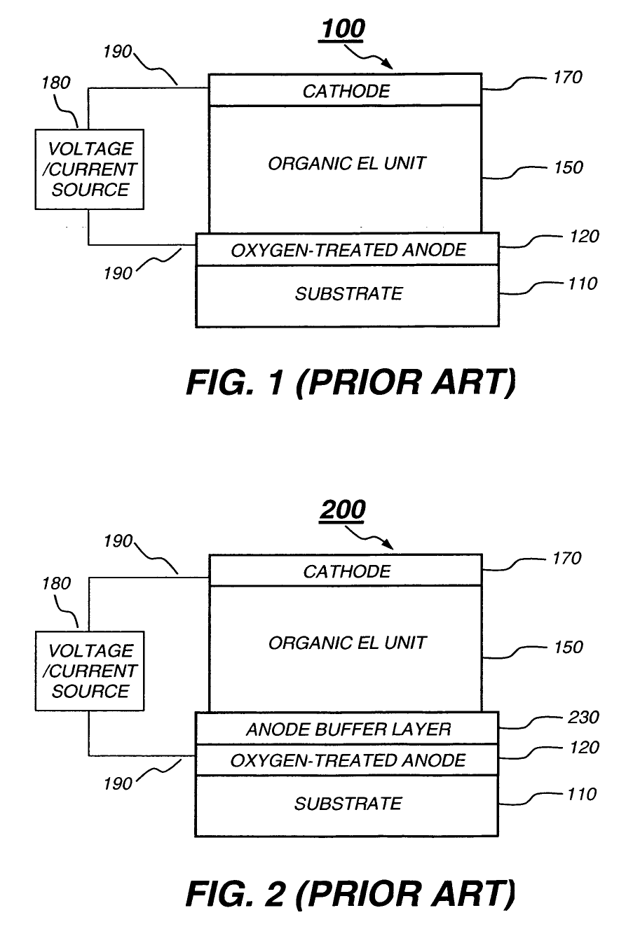

It will be understood that FIGS. 1-8 are not to scale since the individual layers are too thin and the thickness differences of various layers are too great to permit depiction to scale.

### DETAILED DESCRIPTION OF THE INVENTION

In order to more fully appreciate the construction and the performance of the OLED in the present invention, several prior art OLEDs will be described with reference to FIGS. 1, 2, and 3, wherein an oxygen-treated anode or an anode buffer layer are used. The present invention is applicable to any OLED having an anode modification layer in direct contact with a non-oxygen-treated anode. The term “oxygen-treated anode” means that the anode surface is treated by any method, such as oxygen plasma treatment, or UV ozone treatment, to enrich the oxygen content on the anode surface. As a result, the oxygen content on the surface is at least 5%, in atomic ratio, higher than that in most of the anode. The surface oxygen content and most of the oxygen content can be measured by an x-ray photoelectron spectroscopy (XPS) or a secondary ion mass spectroscopy (SIMS) by obtaining a compositional depth profile. The term “non-oxygen-treated anode” means that the anode surface is not treated by any method, which can enrich the oxygen content on the anode surface. As a result, the oxygen content on the surface is typically not 5% higher than that in most of the anode. However, the surface of the “non-oxygen-treated anode” can be treated by any other method, such as wet cleaning process, argon plasma treatment, nitrogen plasma treatment, or thermal annealing, which will not enrich the surface oxygen content.

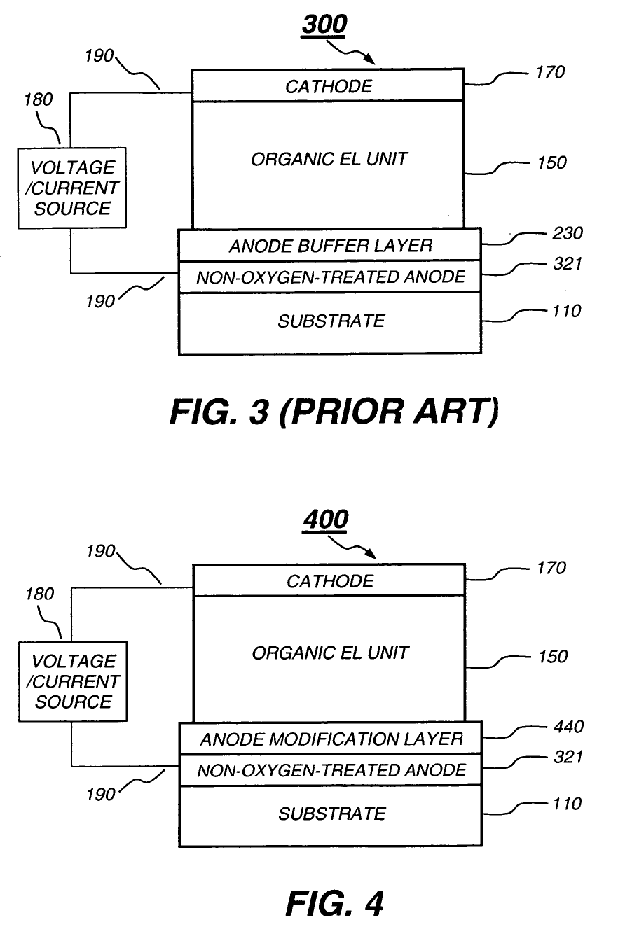

There is shown a cross-sectional view of a prior art OLED in FIG. 1. OLED 100 includes substrate 110, oxygen-treated anode 120, organic EL unit 150, and cathode 170. OLED 100 is externally connected to a voltage/current source 180 through electrical conductors 190. OLED 100 is operated by applying an electric potential produced by the voltage/current source 180 between the pair of contact electrodes, anode 120 and cathode 170. There is also shown a cross-sectional view of another prior art OLED in FIG. 2. OLED 200 in FIG. 2 is the same as OLED 100 in FIG. 1 except that there is an anode buffer layer 230 disposed between the oxygen-treated anode 120 and the organic EL unit 150. There is also shown a cross-sectional view of another prior art OLED in FIG. 3. OLED 300 in FIG. 3 is the same as OLED 200 in FIG. 2 except that the anode buffer layer 230 is disposed in direct contact with a non-oxygen-treated anode 321.

The prior art OLEDs in FIGS. 1 and 2 have an oxygen-treated anode 120, such as an oxygen-treated ITO anode, formed over substrate 110. Since as-prepared anode or an as-patterned anode typically cannot be used as an effective anode for OLED, anode surface needs to be modified to become a high work function surface before the formation of organic EL unit on the surface. A common way to modify the anode surface is oxygen treatment, such as oxygen plasma treatment or UV ozone treatment. Therefore, in a real device fabrication, the anode used for OLED is typically an oxygen-treated anode.

The prior art OLEDs in FIGS. 2 and 3 have an anode buffer layer 230 formed over an oxygen-treated anode 120, such as an oxygen-treated ITO anode, or a non-oxygen-treated anode 321, such as an in situ prepared metal anode. The anode buffer layer 230 can serve to facilitate hole injection from the anode into the organic EL unit and to improve the film formation property of subsequent organic layers. The anode buffer layer typically has a thickness less than 5 nm. Suitable materials for use in the anode buffer layer 230 include, but are not limited to, plasma-deposited fluorocarbon polymers (denoted as CFₓ) as described in U.S. Pat. No. 6,208,075. Alternative materials for use in the anode buffer layer 230 include inorganic compounds as described in U.S. Patent Application Publication 2004/0113547 A1, such as aluminum oxide, titanium oxide, zinc oxide, ruthenium oxide, nickel oxide, zirconium oxide, tantalum oxide, magnesium oxide, calcium oxide, strontium oxide, vanadium oxide, yttrium oxide, lithium oxide, cesium oxide, chromium oxide, silicon oxide, barium oxide, manganese oxide, cobalt oxide, copper oxide, praseodymium oxide, tungsten oxide, germanium oxide, potassium oxide, alkali metal fluorides, or other compounds. OLEDs having the anode buffer layer can have further improved EL performance.

Turning now to FIG. 4, there is shown a cross-sectional view of one embodiment of an OLED with an anode modification layer 440 disposed in direct contact with a non-oxygen-treated anode 321 in accordance with the present invention. The present invention does not use any oxygen-treated anode because the oxygen-rich anode surface is not stable during device operation. The present invention does not use any conventional anode buffer layer because it is difficult to form that layer by using thermal evaporation method and difficult to control the real thickness for lower drive voltage and better operational lifetime, as previously discussed.

The following will be the description of the device structure, material selection, and fabrication process the OLEDs in accordance with the present invention.

Substrate 110 can be an organic solid, an inorganic solid, or include organic and inorganic solids that provide a supporting backplane to hold the OLED. Substrate 110 can be rigid or flexible and can be processed as separate individual pieces, such as sheets or wafers, or as a continuous roll. Typical substrate materials include glass, plastic, metal, ceramic, semiconductor, metal oxide, semiconductor oxide, or semiconductor nitride, or combinations thereof. Substrate 110 can be a homogeneous mixture of materials, a composite of materials, or multiple layers of materials. Substrate 110 can also be a backplane containing TFT circuitry commonly used for preparing OLED display, e.g. an active-matrix low-temperature poly-silicon TFT substrate. The substrate 110 can either be light transmissive or opaque, depending on the intended direction of light emission. The light transmissive property is desirable for viewing the EL emission through the substrate. Transparent glass or plastic are commonly employed in such cases. For applications where the EL emission is viewed through the top electrode, the transmissive characteristic of the bottom support is immaterial, and therefore can be light transmissive, light absorbing or light reflective. Substrates for use in the present invention include, but are not limited to, glass, plastic, semiconductor materials, ceramics, and circuit board materials, or any others commonly used in the formation of OLEDs, which can be either passive-matrix devices or active-matrix devices.

The non-oxygen-treated anode 321 is formed over substrate 110. When EL emission is viewed through the substrate 110, the anode should be transparent or substantially transparent to the emission of interest. For applications where EL emission is viewed through the top electrode, the transmissive characteristics of the anode material are immaterial and any conducting or semiconducting material can be used, regardless if it is transparent, opaque, or reflective. Desired anode materials can be deposited by any suitable way such as thermal evaporation, sputtering, chemical vapor deposition, or electrochemical means. Anode materials can be patterned using well known photolithographic processes.

The material for use to form the non-oxygen-treated anode 321 can be selected from inorganic materials, or organic materials, or combination thereof. The non-oxygen-treated anode 321 can contain the element material selected from aluminum, silver, gold, copper, zinc, indium, tin, titanium, zirconium, hafnium, niobium, tantalum, molybdenum, tungsten, manganese, iron, ruthenium, rhodium, iridium, nickel, palladium, platinum, silicon, or germanium, or combinations thereof. The non-oxygen-treated anode 321 can also contain compound material, such as conducting or semiconducting compound. The conducting or semiconducting compound can be selected from the oxides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. The conducting or semiconducting compound can be selected from the sulfides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. The conducting or semiconducting compound can be selected from the selenides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. The conducting or semiconducting compound can be selected from the tellurides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. The conducting or semiconducting compound can be selected from the nitrides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. Preferably, the conducting or semiconducting compound can be selected from indium-tin oxide, tin oxide, aluminum-doped zinc oxide, indium-doped zinc oxide, magnesium-indium oxide, nickel-tungsten oxide, zinc sulfide, zinc selenide, or gallium nitride, or combinations thereof.

The anode modification layer 440 in the OLED 400 as shown in FIG. 4 is a unique layer in accordance with the present invention. The anode modification layer includes one or more materials, each having an electron-accepting property and a reduction potential greater than 0.0 V vs. a Saturated Calomel Electrode. Preferably, each of the materials has a reduction potential greater than 0.5 V vs. a Saturated Calomel Electrode.

By “electron-accepting property” it is meant that the organic material has the capability or tendency to accept at least some electronic charge from other types of material that it is adjacent to. Having electron-accepting property also means having a strong oxidizing property. The term “reduction potential”, expressed in volts, measures the affinity of a substance for an electron: the higher the positive number the greater the affinity. Reduction of hydronium ions into hydrogen gas would have a reduction potential of 0.00 V under standard conditions. The reduction potential of a substance can be conveniently obtained by cyclic voltammetry (CV) and it is measured vs. SCE. The measurement of the reduction potential of a substance can be as following: A Model CH1660 electrochemical analyzer (CH Instruments, Inc., Austin, Tex.) is employed to carry out the electrochemical measurements. Both CV and Osteryoung square-wave voltammetry (SWV) can be used to characterize the redox properties of the substance. A glassy carbon (GC) disk electrode (A=0.071 cm²) is used as working electrode. The GC electrode is polished with 0.05 μm alumina slurry, followed by sonication cleaning in deionized water twice and rinsed with acetone between the two water cleanings. The electrode is finally cleaned and activated by electrochemical treatment prior to use. A platinum wire can be used as the counter electrode and the SCE is used as a quasi-reference electrode to complete a standard 3-electrode electrochemical cell. A mixture of acetonitrile and toluene (1:1 MeCN/toluene) or methylene chloride (MeCl₂) can be used as organic solvent systems. All solvents used are ultra low water grade (<10 ppm water). The supporting electrolyte, tetrabutylammonium tetrafluoroborate (TBAF) is recrystallized twice in isopropanol and dried under vacuum for three days. Ferrocene (Fc) can be used as an internal standard (E^{red}_{FC}=0.50 V vs. SCE in 1:1 MeCN/toluene, E^{red}_{FC}=0.55 V vs. SCE in MeCl₂, 0.1 M TBAF). The testing solution is purged with high purity nitrogen gas for approximately 15 minutes to remove oxygen and a nitrogen blanket is kept on the top of the solution during the course of the experiments. All measurements are performed at an ambient temperature of 25±1° C. If the compound of interest has insufficient solubility, other solvents can be selected and used by those skilled in the art. Alternatively, if a suitable solvent system cannot be identified, the electron-accepting material can be deposited onto the electrode and the reduction potential of the modified electrode can be measured.

Since the material for use in the anode modification layer 440 is a strong oxidizing agent, it can effectively oxidize the anode surface by accepting charges from the anode material, and can effectively modify the anode surface to form a very stable contact interface. Therefore, by using this anode modification layer, the anode surface can maintain a high work function and form a stable contact interface without producing a hole-injection barrier. Moreover, the anode modification layer can also act as an extra hole-injecting layer (HIL) to provide improved hole injection from the anode into the organic EL unit in the OLED. Since this anode modification layer is used to modify the anode surface, it can be as thin as 0.1 nm. However, as an HIL, it can also be as thick as 200 nm. Preferably, the thickness of the anode modification layer is in the range of from 0.1 to 150 nm. More preferably, the thickness of the anode modification layer is in the range of from 0.1 to 50 nm.

It should be noted that if the organic material having a reduction potential higher than 0.0 V vs. SCE is used as a dopant and a hole-transport material is used as a host to form the anode modification layer, the dopant molecules will not have the oxidizing capability to effectively react with the anode surface to form a stable contact interface, because during the co-evaporation of the dopant and the host materials, the dopant molecules have already accepted some electron charges from the host molecules to form charge-transfer complexes. This layer can only be used as an HIL, instead of an anode modification layer. For example, if 2,3,5,6-tetrafluoro-7,7,8,8-tetracyano-quinodimethane (F₄-TCNQ, which will be discussed later) is used as a dopant to dope into a host-transporting material, F₄-TCNQ will form a complex with the host molecule and no longer have the capability to oxidize anode surface. Therefore, the one or more organic materials having a reduction potential higher than 0.0 V vs. SCE should constitute more than 50% by mole ratio in the anode modification layer.

Several types of organic materials having a reduction potential greater than 0.0 V vs. SCE can be used to form the anode modification layer 440 in the present invention.

The organic material used in the anode modification layer can be a chemical compound of Formula I (2,3,5,6-tetrafluoro-7,7,8,8-tetracyano-quinodimethane (F₄-TCNQ))

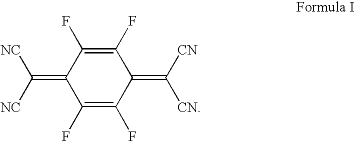

The organic material used in the anode modification layer can also be a chemical compound of Formula II 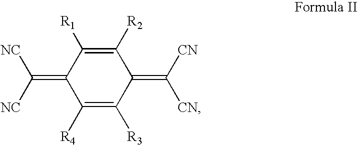
wherein R₁-R₄ represent hydrogen or substituents independently selected from the group including nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, or R₃ and R₄, combine form a ring structure including an aromatic ring, a heteroaromatic ring, or a non-aromatic ring, and each ring is substituted or unsubstituted.

Specifically, the organic material used in the anode modification layer can be a chemical compound of Formula IIa 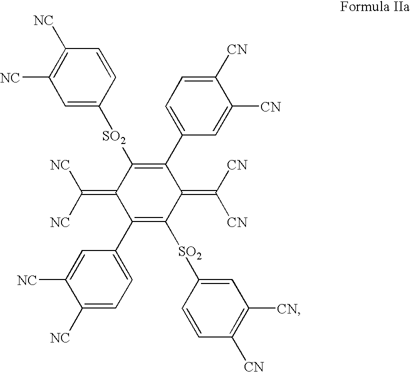
or can be a chemical compound of Formula IIb

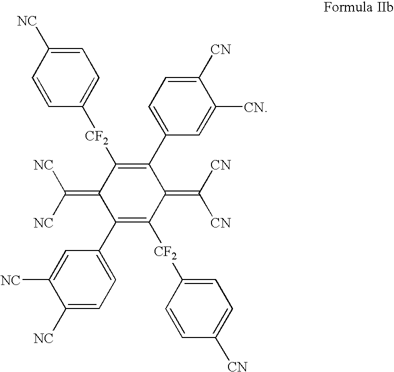

When the non-oxygen-treated anode includes a conducting or semiconducting compound, the organic materials having a reduction potential greater than −0.2 V vs. SCE can also be used to form the anode modification layer 440 in the present invention. Such materials include a chemical compound of Formula III 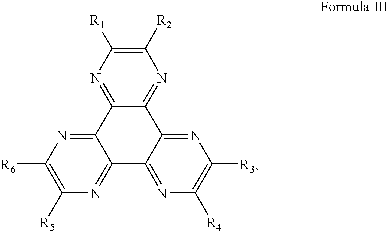
wherein R₁-R₆ represent hydrogen or a substituent independently selected from the group including halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, R₃ and R₄, or R₅ and R₆, combine form a ring structure including an aromatic ring, a heteroaromatic ring, or a non-aromatic ring, and each ring is substituted or unsubstituted.

Specifically, the organic material used in the contaminant-scavenging layer can be a chemical compound of Formula IIIa (hexanitrile hexaazatriphenylene) 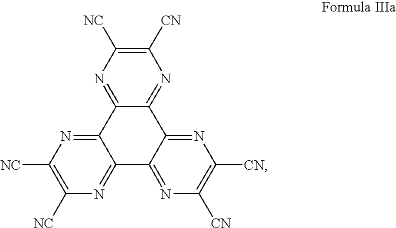
or can be a chemical compound of Formula IIIb 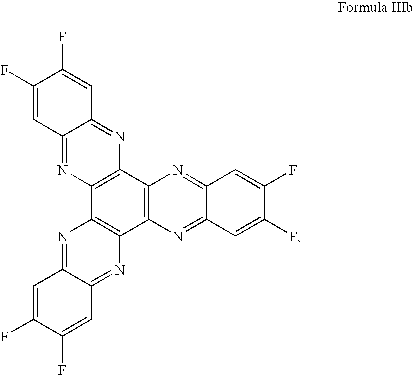
or can be a chemical compound of Formula IIIc 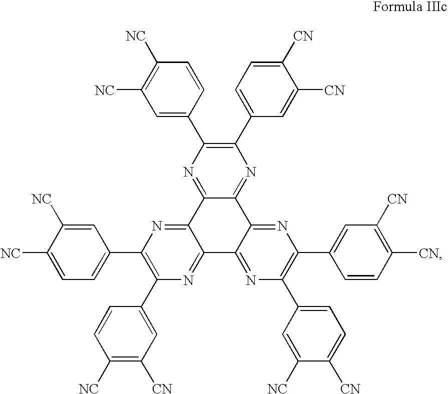
or can be a chemical compound of Formula IIId

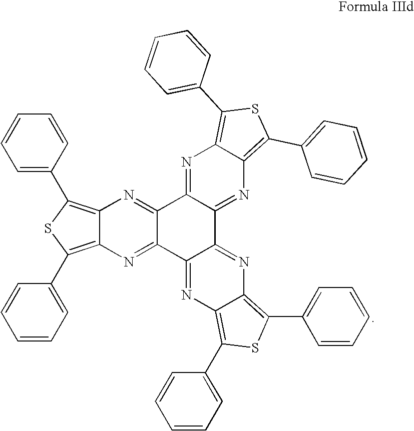

It should also be noted that organic materials suitable for use in the anode modification layer not only include the compounds containing at least carbon and hydrogen, but also include metal complexes, e.g., transition metal complexes having organic ligands and organometallic compounds, as long as their reduction potentials are in the appropriate range.

The organic materials used to form the anode modification layer 340 are suitably deposited through a vapor-phase method such as thermal evaporation, but can be deposited from a fluid, for example, from a solvent with an optional binder to improve film formation. If the material is a polymer, solvent deposition is useful but other methods can be used, such as sputtering or thermal transfer from a donor sheet. Preferably, the organic materials used to form the contaminant-scavenging layer 340 are deposited by thermal evaporation under reduced pressure.

Organic EL unit 150 is capable of supporting hole injection, hole transport, electron injection, electron transport, and electron-hole recombination to produce light. Organic EL unit 150 can comprise a plurality of layers. Such layers can include an HIL, an HTL, a LEL, an ETL, an electron-injecting layer (EIL), hole-blocking layer (HBL), electron-blocking layer (EBL), an exciton-blocking layer (XBL), and others known in the art. Various layers can serve multiple functions (e.g., an ETL can also serve as an HBL), and there can be multiple layers that have a similar function (e.g., there can be several LELs and ETLs). There are many organic EL multilayer structures known in the art that can be used as EL units of the present invention. Some non-limiting examples include, HTL/LEL(s)/ETL, HTL/LEL(s)/EIL, HIL/HTL/LEL(s)/ETL, HIL/HTL/LEL(s)/ETL/EIL, HIL/HTL/EBL or XBL/LEL(s)/ETL/EIL, HIL/HTL/LEL(s)/HBL/ETL/EIL. Preferably, the layer structure of the EL unit is of HTL/LEL(s)/ETL, HIL/HTL/LEL(s)/ETL, or HIL/HTL/LEL(s)/ETL/EIL. Considering the number of the LELs within an organic EL unit 150, the number of LELs in the EL unit can be changed typically from 1 to 3.

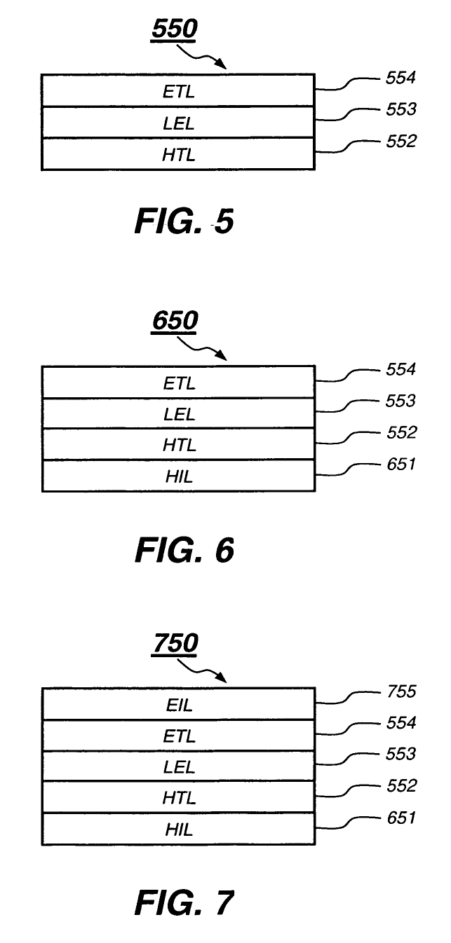

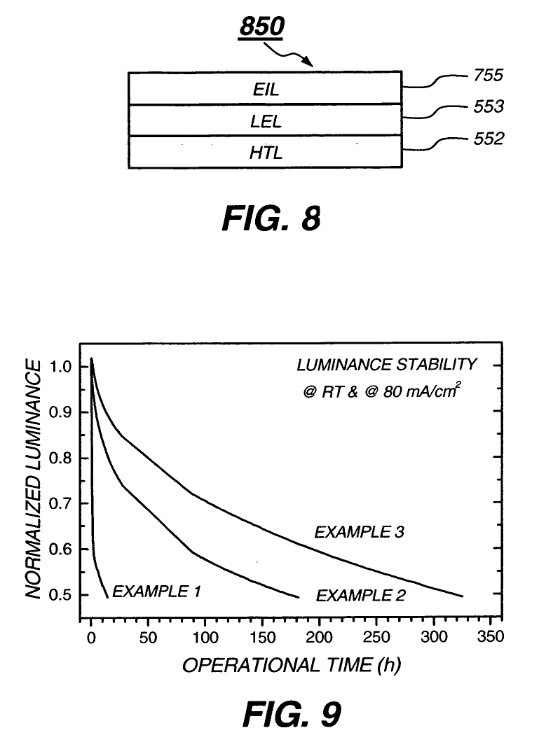

Shown in FIGS. 5, 6, 7, and 8 are exemplary embodiments of organic EL units used in OLEDs in the present invention. Organic EL unit 550 in FIG. 5 includes HTL 552, LEL 553, and ETL 554. Organic EL unit 650 in FIG. 6 includes HIL 651, HTL 552, LEL 553, and ETL 554. Organic EL unit 750 in FIG. 7 includes HIL 651, HTL 552, LEL 553, ETL 554, and EIL 755. Organic EL unit 850 in FIG. 8 includes HTL 552, LEL 553, and EIL 755.

Although not always necessary, it is often useful to provide an HIL in the organic EL unit. HIL 651 in the organic EL units as shown in FIGS. 6 and 7 can serve to facilitate hole injection from the anode into the HTL, thereby reducing the drive voltage of the OLEDs. Suitable materials for use in HIL 651 include, but are not limited to, porphyrinic compounds as described in U.S. Pat. No. 4,720,432 and some aromatic amines, for example, m-MTDATA (4,4′,4″-tris[(3-ethylphenyl)phenylamino]triphenylamine). Alternative hole-injecting materials reportedly useful in organic EL devices are described in EP 0 891 121 A1 and EP 1 029 909 A1. In addition, a p-type doped organic layer is also useful for the HIL as described in U.S. Pat. No. 6,423,429. The term “p-type doped organic layer” means that this layer has semiconducting properties after doping, and the electrical current through this layer is substantially carried by the holes. The conductivity is provided by the formation of a charge-transfer complex as a result of hole transfer from the dopant to the host material.

The HTL 552 in the organic EL units as shown in FIGS. 5, 6, 7, and 8 contains at least one hole-transporting material such as an aromatic tertiary amine, where the aromatic tertiary amine is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals or comprising at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described by VanSlyke in U.S. Pat. No. 4,720,432 and VanSlyke et al. in U.S. Pat. No. 5,061,569. The HTL can be formed of a single or a mixture of aromatic tertiary amine compounds. Illustrative of useful aromatic tertiary amines are the following:
1,1-Bis(4-di-p-tolylaminophenyl)cyclohexane;
1,1-Bis(4-di-p-tolylaminophenyl)-4-phenylcyclohexane;
N,N,N′,N′-tetraphenyl-4,4′″-diamino-1,1′:4′,1″:4″,1′″-quaterphenyl;
Bis(4-dimethylamino-2-methylphenyl)phenylmethane;
1,4-bis[2-[4-[N,N-di(p-toly)amino]phenyl]vinyl]benzene (BDTAPVB);
N,N,N′,N′-Tetra-p-tolyl-4,4′-diaminobiphenyl;
N,N,N′,N′-Tetraphenyl-4,4′-diaminobiphenyl;
N,N,N′,N′-tetra-1-naphthyl-4,4′-diaminobiphenyl;
N,N,N′,N′-tetra-2-naphthyl-4,4′-diaminobiphenyl;
N-Phenylcarbazole;
4,4′-Bis[N-(1-naphthyl)-N-phenylamino]biphenyl (NPB);
4,4′-Bis[N-(1-naphthyl)-N-(2-naphthyl)amino]biphenyl (TNB);
4,4′-Bis[N-(1-naphthyl)-N-phenylamino]ₚ-terphenyl;
4,4′-Bis[N-(2-naphthyl)-N-phenylamino]biphenyl;
4,4′-Bis[N-(3-acenaphthenyl)-N-phenylamino]biphenyl;
1,5-Bis[N-(1-naphthyl)-N-phenylamino]naphthalene;
4,4′-Bis[N-(9-anthryl)-N-phenylamino]biphenyl;
4,4′-Bis[N-(1-anthryl)-N-phenylamino]-p-terphenyl;
4,4′-Bis[N-(2-phenanthryl)-N-phenylamino]biphenyl;
4,4′-Bis[N-(8-fluoranthenyl)-N-phenylamino]biphenyl;
4,4′-Bis[N-(2-pyrenyl)-N-phenylamino]biphenyl;
4,4′-Bis[N-(2-naphthacenyl)-N-phenylamino]biphenyl;
4,4′-Bis[N-(2-perylenyl)-N-phenylamino]biphenyl;
4,4′-Bis[N-(1-coronenyl)-N-phenylamino]biphenyl;
2,6-Bis(di-p-tolylamino)naphthalene;
2,6-Bis[di-(1-naphthyl)amino]naphthalene;
2,6-Bis[N-(1-naphthyl)-N-(2-naphthyl)amino]naphthalene;
N,N,N′,N′-Tetra(2-naphthyl)-4,4″-diamino-p-terphenyl;
4,4′-Bis{N-phenyl-N-[4-(1-naphthyl)-phenyl]amino}biphenyl;
2,6-Bis[N,N-di(2-naphthyl)amino] fluorene;
4,4′,4″-tris[(3-methylphenyl)phenylamino]triphenylamine (MTDATA); and
4,4′-Bis[N-(3-methylphenyl)-N-phenylamino]biphenyl (TPD).

Another class of useful hole-transporting materials includes polycyclic aromatic compounds as described in EP 1 009 041. Tertiary aromatic amines with more than two amino groups can be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

The LEL 553 in the organic EL units as shown in FIGS. 5, 6, 7, and 8 can include a luminescent fluorescent or phosphorescent material where electroluminescence is produced as a result of electron-hole pair recombination in this region. The light-emitting layer can be comprised of a single material, but more commonly contains at least one host material doped with at least one guest emitting material or materials where light emission comes primarily from the emitting materials and can be of any color. This guest emitting material is often referred to as a light emitting dopant. The host materials in the light-emitting layer can be an electron-transporting material, as defined below, a hole-transporting material, as defined above, or another material or combination of materials that support hole-electron recombination. The emitting material is typically chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small nonpolymeric molecules or polymeric materials including polyfluorenes and polyvinylarylenes, e.g., poly(p-phenylenevinylene), PPV. In the case of polymers, small molecule emitting materials can be molecularly dispersed into a polymeric host, or the emitting materials can be added by copolymerizing a minor constituent into a host polymer.

An important relationship for choosing an emitting material is a comparison of the electron energy bandgap, which is defined as the energy difference between the highest occupied molecular orbital and the lowest unoccupied molecular orbital of the molecule. For efficient energy transfer from the host to the emitting material, a necessary condition is that the bandgap of the dopant is smaller than that of the host material. For phosphorescent emitters (including materials that emit from a triplet excited state, i.e., so-called “triplet emitters”) it is also important that the host triplet energy level of the host be high enough to enable energy transfer from host to emitting material.

Host and emitting materials known to be of use include, but are not limited to, those disclosed in U.S. Pat. Nos. 4,768,292, 5,141,671, 5,150,006, 5,151,629, 5,405,709, 5,484,922, 5,593,788, 5,645,948, 5,683,823, 5,755,999, 5,928,802, 5,935,720, 5,935,721, 6,020,078, 6,475,648, 6,534,199, 6,661,023, U.S. Patent Application Publications 2002/0127427 A1, 2003/0198829 A1, 2003/0203234 A1, 2003/0224202 A1, and 2004/0001969 A1.

Metal complexes of 8-hydroxyquinoline (oxine) and similar derivatives constitute one class of useful host compounds capable of supporting electroluminescence. Illustrative of useful chelated oxinoid compounds are the following:

CO-1: Aluminum trisoxine [alias, tris(8-quinolinolato)aluminum(III)];

CO-2: Magnesium bisoxine [alias, bis(8-quinolinolato)magnesium(II)];

CO-3: Bis[benzo{f}-8-quinolinolato]zinc (II);

CO-4: Bis(2-methyl-8-quinolinolato)aluminum(III)-μ-oxo-bis(2-methyl-8-quinolinolato) aluminum(III);

CO-5: Indium trisoxine [alias, tris(8-quinolinolato)indium];

CO-6: Aluminum tris(5-methyloxine) [alias, tris(5-methyl-8-quinolinolato) aluminum(III)];

CO-7: Lithium oxine [alias, (8-quinolinolato)lithium(I)];

CO-8: Gallium oxine [alias, tris(8-quinolinolato)gallium(III)]; and

CO-9: Zirconium oxine [alias, tetra(8-quinolinolato)zirconium(IV)].

Another class of useful host materials includes derivatives of anthracene, such as those described in U.S. Pat. Nos. 5,935,721, 5,972,247, 6,465,115, 6,534,199, 6,713,192, U.S. Patent Application Publications 2002/0048687 A1, 2003/0072966 A1, and WO 2004/018587. Some examples include derivatives of 9,10-dinaphthylanthracene derivatives and 9-naphthyl-10-phenylanthracene. Other useful classes of host materials include distyrylarylene derivatives as described in U.S. Pat. No. 5,121,029, and benzazole derivatives, for example, 2,2′,2″-(1,3,5-phenylene)tris[1-phenyl-1H-benzimidazole].

Desirable host materials are capable of forming a continuous film. The light-emitting layer can contain more than one host material in order to improve the device's film morphology, electrical properties, light emission efficiency, and lifetime. Mixtures of electron-transporting and hole-transporting materials are known as useful hosts. In addition, mixtures of the above listed host materials with hole-transporting or electron-transporting materials can make suitable hosts.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)amine boron compounds, bis(azinyl)methane boron compounds, derivatives of distryrylbenzene and distyrylbiphenyl, and carbostyryl compounds. Among derivatives of distyrylbenzene, particularly useful are those substituted with diarylamino groups, informally known as distyrylamines.

Suitable host materials for phosphorescent emitters should be selected so that the triplet exciton can be transferred efficiently from the host material to the phosphorescent material. For this transfer to occur, it is a highly desirable condition that the excited state energy of the phosphorescent material be lower than the difference in energy between the lowest triplet state and the ground state of the host. However, the band gap of the host should not be chosen so large as to cause an unacceptable increase in the drive voltage of the OLED. Suitable host materials are described in WO 00/70655 A2, WO 01/39234 A2, WO 01/93642 A1, WO 02/074015 A2, WO 02/15645 A1, and U.S. Patent Application Publication 2002/0117662 A1. Suitable hosts include certain aryl amines, triazoles, indoles and carbazole compounds. Examples of desirable hosts are 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinylcarbazole), including their derivatives.

Examples of useful phosphorescent dopants that can be used in light-emitting layers of this invention include, but are not limited to, those described in WO 00/57676, WO 00/70655, WO 01/41512 A1, WO 02/15645 A1, WO 01/93642 A1, WO 01/39234 A2, WO 02/074015 A2, WO 02/071813 A1, U.S. Pat. Nos. 6,458,475, 6,573,651, 6,413,656, 6,515,298, 6,451,415, 6,097,147, 6,451,455, U.S. Patent Application Publications 2003/0017361 A1, 2002/0197511 A1, 2003/0072964 A1, 2003/0068528 A1, 2003/0124381 A1, 2003/0059646 A1, 2003/0054198 A1, 2002/0100906 A1, 2003/0068526 A1, 2003/0068535 A1, 2003/0141809 A1, 2003/0040627 A1, 2002/0121638 A1, EP 1 239 526 A2, EP 1 238 981 A2, EP 1 244 155 A2, JP 2003-073387, JP 2003-073388, JP 2003-059667, and JP 2003-073665. Preferably, useful phosphorescent dopants include transition metal complexes, such as iridium and platinum complexes.

In some cases it is useful for one or more of the LELs within an EL unit to emit broadband light, for example white light. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. Nos. 5,683,823, 5,503,910, 5,405,709, 5,283,182, 6,627,333, 6,696,177, 6,720,092, and U.S. Patent Application Publications 2002/0186214 A1, 2002/0025419 A1, and 2004/0009367 A1. In some of these systems, the host for one light-emitting layer is a hole-transporting material.

Preferred organic materials for use in forming the ETL 554 in the organic EL units as shown in FIGS. 5, 6, and 7 are metal chelated oxinoid compounds, including chelates of oxine itself, also commonly referred to as 8-quinolinol or 8-hydroxyquinoline. Such compounds help to inject and transport electrons, exhibit high levels of performance, and are readily deposited to form thin films. Exemplary oxinoid compounds have been listed above from CO-1 to CO-9. (The oxinoid compounds can be used as both the host material in LEL 553 and the electron-transporting material in ETL 554).

Other electron-transporting materials include various butadiene derivatives as disclosed in U.S. Pat. No. 4,356,429 and various heterocyclic optical brighteners as described in U.S. Pat. No. 4,539,507. Benzazoles, oxadiazoles, triazoles, pyridinethiadiazoles, triazines, phenanthroline derivatives, and some silole derivatives are also useful electron-transporting materials.

The EIL 755 in the organic EL units as shown in FIGS. 7 and 8 is an n-type doped layer containing at least one electron-transporting material as a host material and at least one n-type dopant (This EIL can also be called an n-type doped EIL 755). The term “n-type doped layer” means that this layer has semiconducting properties after doping, and the electrical current through this layer is substantially carried by the electrons. The host material is capable of supporting electron injection and electron transport. The electron-transporting materials used in ETL 554 represent a useful class of host materials for the n-type doped EIL 755. Preferred materials are metal chelated oxinoid compounds, including chelates of oxine itself (also commonly referred to as 8-quinolinol or 8-hydroxyquinoline), such as tris(8-hydroxyquinoline)aluminum (Alq). Other materials include various butadiene derivatives as disclosed by Tang in U.S. Pat. No. 4,356,429, various heterocyclic optical brighteners as disclosed by Van Slyke et al. in U.S. Pat. No. 4,539,507, triazines, hydroxyquinoline derivatives, benzazole derivatives, and phenanthroline derivatives. Silole derivatives, such as 2,5-bis(2′,2″-bipridin-6-yl)-1,1-dimethyl-3,4-diphenyl silacyclopentadiene are also useful host organic materials. The combination of the aforementioned host materials is also useful to form the n-typed doped EIL 755. More preferably, the host material in the n-type doped EIL 755 includes Alq, 4,7-diphenyl-1,10-phenanthroline (Bphen), 2,9-dimethyl-4,7-diphenyl-1,10-phenanthroline (BCP), or 2,2′-[1,1′-biphenyl]-4,4′-diylbis[4,6-(p-tolyl)-1,3,5-triazine] (TRAZ), or combinations thereof.

Both EIL 755 and ETL 554 in the EL units in the OLEDs can use the same or different material.

The n-type dopant in the n-type doped EIL 755 includes alkali metals, alkali metal compounds, alkaline earth metals, or alkaline earth metal compounds, or combinations thereof. The term “metal compounds” includes organometallic complexes, metal-organic salts, and inorganic salts, oxides and halides. Among the class of metal-containing n-type dopants, Li, Na, K, Rb, Cs, Mg, Ca, Sr, Ba, La, Ce, Sm, Eu, Th, Dy, or Yb, and their compounds, are particularly useful. The materials used as the n-type dopants in the n-type doped EIL 325 also include organic reducing agents with strong electron-donating properties. By “strong electron-donating properties” it is meant that the organic dopant should be able to donate at least some electronic charge to the host to form a charge-transfer complex with the host. Non-limiting examples of organic molecules include bis(ethylenedithio)-tetrathiafulvalene (BEDT-TTF), tetrathiafulvalene (TTF), and their derivatives. In the case of polymeric hosts, the dopant can be any of the above or also a material molecularly dispersed or copolymerized with the host as a minor component. Preferably, the n-type dopant in the n-type doped EIL 755 includes Li, Na, K, Rb, Cs, Mg, Ca, Sr, Ba, La, Ce, Nd, Sm, Eu, Th, Dy, or Yb, or combinations thereof. The n-type doped concentration is preferably in the range of 0.01-20% by volume. The thickness of the n-type doped EIL 755 is typically less than 200 nm, and preferably in the range of less than 150 nm.

Additional layers such as electron or hole-blocking layers can be employed in the organic EL units in the OLEDs. Hole-blocking layers are commonly used to improve efficiency of phosphorescent emitter devices, for example, as in U.S. Patent Application Publication 2002/0015859 A1.

In some instances, LEL 553 and ETL 554 in the organic EL units can optionally be collapsed into a single layer that serves the function of supporting both light emission and electron transportation. It is also known in the art that emitting dopants can be added to the HTL 552, thereby enabling HTL 552 to serve as a host. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in U.S. Patent Application Publication 2002/0025419 A1, U.S. Pat. Nos. 5,683,823, 5,503,910, 5,405,709, 5,283,182, EP 1 187 235, and EP 1 182 244.

Each of the layers in the organic EL unit 150 can be formed from small molecule (or nonpolymeric) materials (including fluorescent materials and phosphorescent materials), polymeric LED materials, or inorganic materials, or combinations thereof.

The organic materials in the organic EL unit 150 mentioned above are suitably deposited through a vapor-phase method such as thermal evaporation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by thermal evaporation can be vaporized from an evaporation “boat” often comprised of a tantalum material, e.g., as described in U.S. Pat. No. 6,237,529, or can be first coated onto a donor sheet and then sublimed in closer proximity to the substrate. Layers with a mixture of materials can use separate evaporation boats or the materials can be premixed and coated from a single boat or donor sheet. For full color display, the pixelation of LELs may be needed. This pixelated deposition of LELs can be achieved using shadow masks, integral shadow masks, U.S. Pat. No. 5,294,870, spatially defined thermal dye transfer from a donor sheet, U.S. Pat. Nos. 5,688,551, 5,851,709, and 6,066,357, and inkjet method, U.S. Pat. No. 6,066,357. For other organic layers either in the organic EL units or in the intermediate connectors, pixelated deposition is not necessarily needed.

When light emission is viewed solely through the anode, the cathode 170 can be comprised of nearly any conductive material. Desirable materials have effective film-forming properties to ensure effective contact with the underlying organic layer, promote electron injection at low voltage, and have effective stability. Useful cathode materials often contain a low work-function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin inorganic EIL (or cathode buffer layer) in contact with an organic layer (e.g., ETL or organic EIL), which is capped with a thicker layer of a conductive metal. Here, the inorganic EIL preferably includes a low work-function metal or metal salt and, if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, the cathode should be transparent or nearly transparent. For such applications, metals should be thin or one should use transparent conductive oxides, or include these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, and EP 1 076 368. Cathode materials are typically deposited by thermal evaporation, electron beam evaporation, ion sputtering, or chemical vapor deposition. When needed, patterning can be achieved through many well known methods including, but not limited to, through-mask deposition, integral shadow masking, for example as described in U.S. Pat. No. 5,276,380 and EP 0 732 868, laser ablation, and selective chemical vapor deposition.

Most OLEDs are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

### EXAMPLES

The following examples are presented for a further understanding of the present invention. In the following examples, the reduction potential of the materials were measured using a Model CHI660 electrochemical analyzer (CH Instruments, Inc., Austin, Tex.) with the method as discussed before. During the fabrication of OLEDs, the thickness of the organic layers and the doping concentrations were controlled and measured in situ using calibrated thickness monitors (INFICON IC/5 Deposition Controller). The EL characteristics of all the fabricated devices were evaluated using a constant current source (KEITHLEY 2400 SourceMeter) and a photometer (PHOTO RESEARCH SpectraScan PR 650) at room temperature. Operational stabilities of the devices were tested either at room temperature or at 85° C. under the direct current of 80 mA/cm².

### Example 1 (Comparative)

The preparation of a conventional OLED is as follows: A ˜1.1 mm thick glass substrate coated with a transparent indium-tin-oxide (ITO) conducting layer was cleaned and dried using a commercial glass scrubber tool. The thickness of ITO is about 42 nm and the sheet resistance of the ITO is about 68 Ω/square. This ITO anode is considered as a non-oxygen-treated anode. The substrate was then transferred into a vacuum deposition chamber for deposition of all other layers on top of the anode. The following layers were deposited in the following sequence by evaporation from a heated boat under a vacuum of approximately 10⁻⁶ Torr:

1. EL Unit:

a) an HTL, 90 nm thick, including “4,4′-bis[N-(1-naphthyl)-N-phenylamino]biphenyl” (NPB);

b) a LEL, 30 nm thick, including “tris(8-hydroxyquinoline)-aluminum” (Alq) doped with 1.0 vol % 10-(2-benzothiazolyl)-1,1,7,7-tetramethyl-2,3,6,7-tetrahydro-1H,5H,11H(1)benzopyrano(6,7,8-ij)quinolizin-11-one (C545T); and

c) an EIL, 30 nm thick, including Alq doped with 1.2 vol % lithium.

2. Cathode: approximately 210 nm thick, including Mg:Ag (formed by co-evaporation of about 95 vol. % Mg and 5 vol. % Ag)

After the deposition of these layers, the device was transferred from the deposition chamber into a dry box (VAC Vacuum Atmosphere Company) for encapsulation. The OLED has an emission area of 10 mm².

This OLED, having a non-oxygen-treated anode, requires a drive voltage of about 14.3 V to pass 20 mA/cm². Under this test condition, the device has a luminance of 2823 cd/m², and a luminous efficiency of about 14.1 cd/A. Its emission peak is at 520 nm. The operational lifetime was measured as T₅₀(RT@80 mA/cm²) (i.e. a time at which the luminance retains 50% of its initial value after being operated at room temperature and at 80 mA/cm²). Its T₅₀(RT@80 mA/cm²) is about 13 hours. Its luminance vs. operational time, tested at room temperature and at 80 mA/cm², is shown in FIG. 9.

### Example 2 (Comparative)

Another OLED was constructed as the same as that in Example 1, except that the non-oxygen-treated ITO anode was subsequently treated with oxygen plasma to modify the surface as an oxygen-treated anode before the deposition of the organic EL unit.

This OLED, having an oxygen-treated anode, requires a drive voltage of about 5.2 V to pass 20 mA/cm². Under this test condition, the device has a luminance of 2170 cd/m², and a luminous efficiency of about 10.9 cd/A. Its emission peak is at 520 nm. The operational lifetime, measured as T₅₀(RT@80 mA/cm²), is about 170 hours. Its luminance vs. operational time, tested at room temperature and at 80 mA/cm², is shown in FIG. 9.

### Example 3 (Inventive)

An OLED in accordance with the present invention was constructed as the same as that in Example 1, except that an anode modification layer with 0.2-nm-thick F₄-TCNQ was subsequently deposited on the non-oxygen-treated ITO surface before the deposition of the organic EL unit. The reduction potential of F₄-TCNQ was measured as about 0.64 V vs. SCE in the 1:1 MeCN/MePh organic solvent system.

This OLED, having an anode modification layer in direct contact with the non-oxygen-treated anode, requires a drive voltage of about 4.9 V to pass 20 mA/cm². Under this test condition, the device has a luminance of 1933 cd/m², and a luminous efficiency of about 9.7 cd/A. Its emission peak is at 520 nm. The operational lifetime, measured as T₅₀(RT@80 mA/cm²), is about 320 hours (Just for a convenient comparison, it is worthwhile to know that if this device were operated at room temperature and at 20 mA/cm², its operational lifetime would be at least 6 time longer, i.e. its T₅₀(RT@20 mA/cm²) would be greater than 320×6=1920 hours. Further, if this device were operated at room temperature with an initial luminance of 100 cd/m², its T₅₀(RT@100 cd/m²) will be expected greater than 320×6×1933÷100≈37,000 hours). Its luminance vs. operational time, tested at room temperature and at 80 mA/cm², is shown in FIG. 9.

It is evident from FIG. 9 that the OLED having a non-oxygen-treated anode does not last long during operation and the OLED having an oxygen-treated anode can have improved operational stability. Moreover, the OLED having an anode modification layer in direct contact with the non-oxygen-treated anode can have dramatic improvement in operational stability, and its lifetime is almost double of that of the OLED having an oxygen-treated anode.

### Example 4 (Comparative)

The preparation of a conventional OLED is as follows:

A ˜1.1 mm thick glass substrate coated with a transparent indium-tin-oxide (ITO) conducting layer was cleaned and dried using a commercial glass scrubber tool. The thickness of ITO is about 42 nm and the sheet resistance of the ITO is about 68 Ω/square. This ITO anode is considered as a non-oxygen-treated anode. The substrate was then transferred into a vacuum deposition chamber for deposition of all other layers on top of the anode. The following layers were deposited in the following sequence by evaporation from a heated boat under a vacuum of approximately 10⁻⁶ Torr:

1. EL Unit:

a) an HTL, 75 nm thick, including NPB;

b) a LEL, 30 nm thick, including Alq doped with 1.0 vol % C545T; and

c) an ETL, 30 nm thick, including Alq.

2. Cathode: approximately 210 nm thick, including Mg:Ag

After the deposition of these layers, the device was transferred from the deposition chamber into a dry box (VAC Vacuum Atmosphere Company) for encapsulation. The OLED has an emission area of 10 mm².

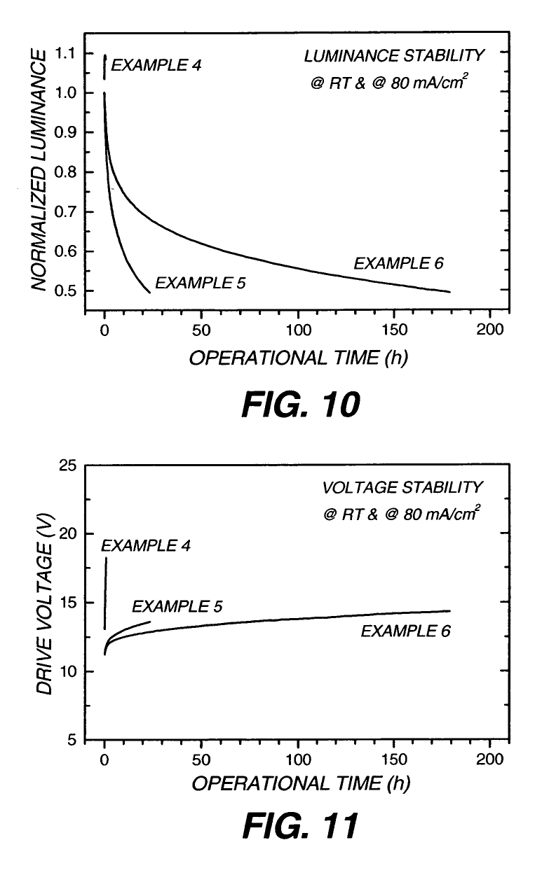

This OLED, having a non-oxygen-treated anode, requires a drive voltage of about 8.3 V to pass 20 mA/cm². Under this test condition, the device has a luminance of 1899 cd/m², and a luminous efficiency of about 9.5 cd/A. Its emission peak is at 520 nm. The operational lifetime, measured as T₅₀(RT@80 mA/cm², is less than 1 hour due to electrical shorting. Its luminance vs. operational time and its drive voltage vs. operational time, tested at room temperature and at 80 mA/cm², are shown in FIGS. 10 and 11, respectively.

### Example 5 (Comparative)

Another OLED was constructed as the same as that in Example 4, except that the non-oxygen-treated ITO anode was subsequently treated with oxygen plasma to modify the surface as an oxygen-treated anode before the deposition of the organic EL unit.

This OLED, having an oxygen-treated anode, requires a drive voltage of about 6.4 V to pass 20 mA/cm². Under this test condition, the device has a luminance of 1813 cd/m², and a luminous efficiency of about 9.1 cd/A. Its emission peak is at 520 nm. The operational lifetime, measured as T₅₀(RT@80 mA/cm²), is about 22 hours. Its luminance vs. operational time and its drive voltage vs. operational time, tested at room temperature and at 80 mA/cm², are shown in FIGS. 10 and 11, respectively.

### Example 6 (Comparative)

A standard OLED was constructed as the same as that in Example 5, except that a layer of CFx, 1 nm thick, was deposited on the oxygen-treated ITO surface as the anode buffer layer by decomposing CHF₃ gas in an RF plasma treatment chamber.

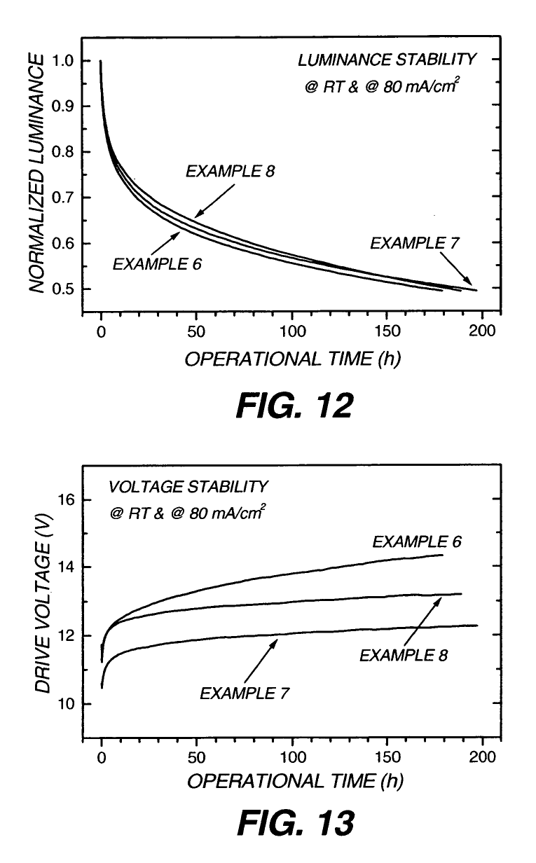

This standard OLED, having an anode buffer layer in direct contact with the oxygen-treated anode, requires a drive voltage of about 6.5 V to pass 20 mA/cm². Under this test condition, the device has a luminance of 1773 cd/m², and a luminous efficiency of about 8.9 cd/A. Its emission peak is at 520 nm. The operational lifetime, measured as T₅₀(RT@80 mA/cm²), is about 169 hours. Its luminance vs. operational time and its drive voltage vs. operational time, tested at room temperature and at 80 mA/cm², are shown in FIGS. 10 and 11, respectively, and are also shown in FIGS. 12 and 13, respectively.

FIGS. 10 and 11 demonstrate that in the prior art OLEDs, the OLED having CFₓ as an anode buffer layer has superior operational stability.

### Example 7 (Inventive)

An OLED, having an anode modification layer in direct contact with a non-oxygen-treated anode, was constructed in accordance with the present invention. This OLED is the same as that in Example 4, except that 1) a layer of hexanitrile hexaazatriphenylene, 10 nm thick, was deposited on the non-oxygen-treated ITO surface as the anode modification layer, and 2) the thickness of the HTL (NPB layer) in the organic EL unit was reduced from 75 nm to 65 nm.

This OLED requires a drive voltage of about 6.2 V to pass 20 mA/cm². Under this test condition, the device has a luminance of 1703 cd/m², and a luminous efficiency of about 8.5 cd/A. Its emission peak is at 520 nm. The operational lifetime, measured as T₅₀(RT@80 mA/cm²), is about 188 hours. Its luminance vs. operational time and its drive voltage vs. operational time, tested at room temperature and at 80 mA/cm², are shown in FIGS. 12 and 13, respectively.

### Example 8 (Comparative)

An OLED, having an anode modification layer in direct contact with an oxygen-treated anode, was constructed. This OLED is the same as that in Example 4, except that 1) a layer of hexanitrile hexaazatriphenylene, 10 nm thick, was deposited on the oxygen-treated ITO surface as the anode modification layer, and 2) the thickness of the HTL (NPB layer) in the organic EL unit was reduced from 75 nm to 65 nm.

This OLED requires a drive voltage of about 6.8 V to pass 20 mA/cm². Under this test condition, the device has a luminance of 1759 cd/m², and a luminous efficiency of about 8.8 cd/A. Its emission peak is at 520 nm. The operational lifetime, measured as T₅₀(RT@80 mA/cm²), is about 181 hours. Its luminance vs. operational time and its drive voltage vs. operational time, tested at room temperature and at 80 mA/cm², are shown in FIGS. 12 and 13, respectively.

It is evident from FIGS. 12 and 13 that the OLEDs having an anode modification layer have obvious improvement in their operational stability, which is comparable or better than that of the standard OLED (Example 6). Especially, their voltage rise during operation is much less than that of the standard OLED. However, it will be indicated in the following examples that the OLED having an oxygen-treated anode will have very poor operational stability at high temperature and high operational current density, even though there is an anode modification layer on the anode.

### Example 9 (Inventive)

An OLED, having an anode modification layer in direct contact with a non-oxygen-treated anode, was constructed in accordance with the present invention. This OLED is the same as that in Example 7 and was used for high temperature test.

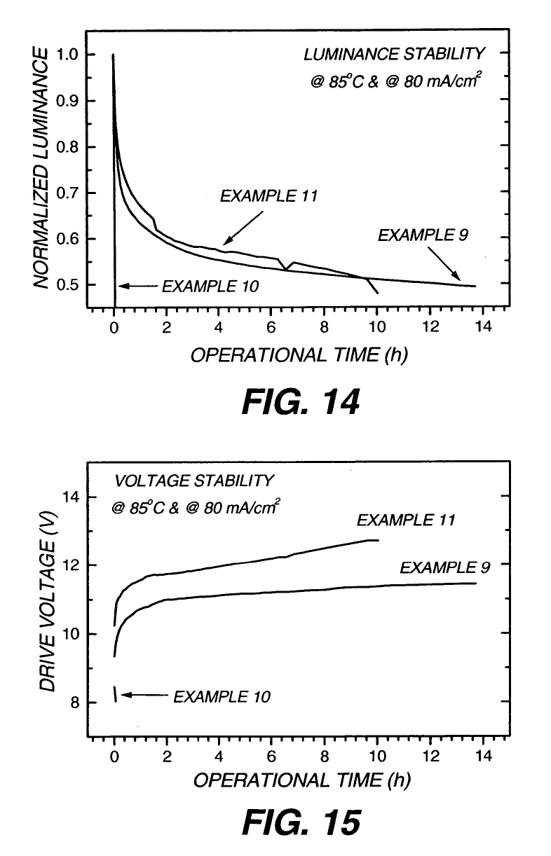

This OLED requires a drive voltage of about 6.3 V to pass 20 mA/cm². Under this test condition, the device has a luminance of 1755 cd/m², and a luminous efficiency of about 8.8 cd/A. Its emission peak is at 520 nm. The operational lifetime, measured as T₅₀(85° C.@80 mA/cm²), is about 12 hours. Its luminance vs. operational time and its drive voltage vs. operational time, tested at 85° C. and at 80 mA/cm², are shown in FIGS. 14 and 15, respectively.

### Example 10 (Comparative)

An OLED, having an anode modification layer in direct contact with an oxygen-treated anode, was constructed. This OLED is the same as that in Example 8 and was used for high temperature test.

This OLED requires a drive voltage of about 6.7 V to pass 20 mA/cm². Under this test condition, the device has a luminance of 1757 cd/m², and a luminous efficiency of about 8.8 cd/A. Its emission peak is at 520 nm. The operational lifetime, measured as T₅₀(85° C.@80 mA/cm²), is less than 0.05 hour (3 min). Its luminance vs. operational time and its drive voltage vs. operational time, tested at 85° C. and at 80 mA/cm², are shown in FIGS. 14 and 15, respectively.

### Example 11 (Comparative)

A standard OLED was constructed as the same as that in Example 6 and was used for high temperature test.

This standard OLED requires a drive voltage of about 6.4 V to pass 20 mA/cm². Under this test condition, the device has a luminance of 1796 cd/m², and a luminous efficiency of about 9.0 cd/A. Its emission peak is at 520 nm. The operational lifetime, measured as T₅₀(85° C.@80 mA/cm²), is about 10 hours. Its luminance vs. operational time and its drive voltage vs. operational time, tested at 85° C. and at 80 mA/cm², are shown in FIGS. 14 and 15, respectively.

The stability test condition of 85° C. and 80 mA/cm² is an extreme condition to exam the quality of OLEDs. It is evident from FIGS. 14 and 15 that although the OLEDs, having an anode modification layer in direct contact with either a non-oxygen-treated anode or an oxygen-treated anode, have similar EL performance at room temperature as shown in FIG. 12, the OLED having an oxygen-treated anode (Example 10) is very unstable when it is operated at high temperature. It is believed that extra oxygen or metal ions on the anode surface would diffuse or electrically migrate into organic EL unit to deteriorate the contact interface between the anode and the organic EL unit and quench the light emission in the LEL. Moreover, the OLED having an anode modification layer in direct contact with a non-oxygen-treated anode has better voltage stability than that of the standard OLED (Example 11) even though it is operated at high temperature. That is why an oxygen-treated anode is not suggested for use in the present invention.

The invention has been described in detail with particular reference to certain preferred embodiments thereof, but it will be understood that variations and modifications can be effected within the spirit and scope of the invention.

### Parts List

100 OLED of prior art
110 substrate
120 oxygen-treated anode
150 organic EL unit
170 cathode
180 voltage/current source
190 electrical conductors
200 OLED of prior art
230 anode buffer layer
300 OLED of prior art
321 non-oxygen-treated anode
400 OLED of present invention
440 anode modification layer
550 organic EL unit
552 hole-transporting layer
553 light-emitting layer
554 electron-transporting layer
650 organic EL unit
651 hole-injecting layer
750 organic EL unit
755 electron-injecting layer
850 organic EL unit

1. An OLED comprising:
a) an anode formed over a substrate, wherein the anode is a non-oxygen-treated anode;
b) an anode modification layer formed in direct contact with the anode, wherein the anode modification layer includes one or more organic materials, each having an electron-accepting property and a reduction potential greater than 0.0 V vs. a Saturated Calomel Electrode, and wherein the one or more organic materials provide more than 50% by mole ratio of the anode modification layer;
c) an organic electroluminescent unit formed over the anode modification layer, wherein the organic electroluminescent unit includes at least a hole-transporting layer and a light-emitting layer; and
d) a cathode formed over the organic electroluminescent unit.

2. The OLED of claim 1 wherein the anode contains the material selected from inorganic materials, or organic materials, or combinations thereof.

3. The OLED of claim 1 wherein the anode contains the element material selected from aluminum, silver, gold, copper, zinc, indium, tin, titanium, zirconium, hafnium, niobium, tantalum, molybdenum, tungsten, manganese, iron, ruthenium, rhodium, iridium, nickel, palladium, platinum, silicon, or germanium, or combinations thereof.

4. The OLED of claim 1 wherein the anode modification layer has a thickness range of from 0.1 to 150 nm.

5. The OLED of claim 1 wherein the anode modification layer has a thickness range of from 0.1 to 50 nm.

6. The OLED of claim 1 wherein the anode modification layer includes a chemical compound:

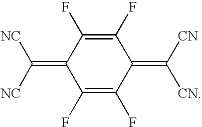

7. The OLED of claim 1 wherein the anode modification layer includes a chemical compound: 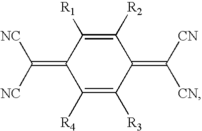
wherein R₁-R₄ represent hydrogen or substituents independently selected from the group including nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, or R₃ and R₄, combine form a ring structure including an aromatic ring, a heteroaromatic ring, or a non-aromatic ring, and each ring is substituted or unsubstituted.

8. The OLED of claim 8 wherein the anode modification layer includes a chemical compound

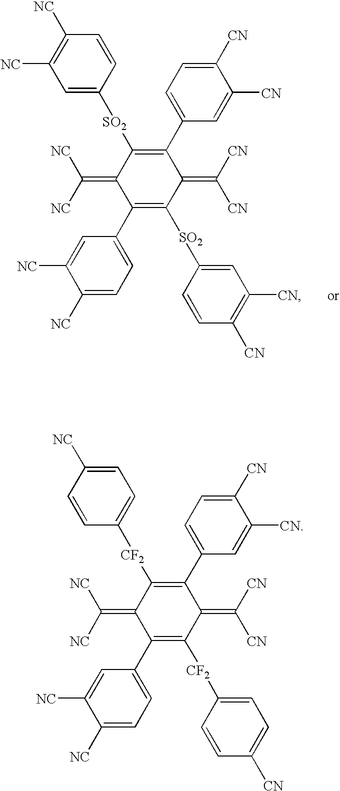

9. The OLED of claim 1 wherein the anode modification layer is formed under reduced pressure.

10. The OLED of claim 1 wherein the organic electroluminescent unit emits a red, green, blue, or white color.

11. An OLED comprising:
a) an anode having an conducting or semiconducting compound formed over a substrate, wherein the anode is a non-oxygen-treated anode;
b) an anode modification layer formed in direct contact with the anode, wherein the anode modification layer includes one or more organic materials, each having an electron-accepting property and a reduction potential greater than −0.2 V vs. a Saturated Calomel Electrode, and wherein the one or more organic materials provide more than 50% by mole ratio of the anode modification layer;
c) an organic electroluminescent unit formed over the anode modification layer, wherein the organic electroluminescent unit includes at least a hole-transporting layer and a light-emitting layer; and
d) a cathode formed over the organic electroluminescent unit.

12. The OLED of claim 9 wherein the anode modification layer has a thickness range of from 0.1 to 150 nm.

13. The OLED of claim 9 wherein the anode contains the material selected from the conducting or semiconducting oxides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof.

14. The OLED of claim 9 wherein the anode contains the material selected from the conducting or semiconducting sulfides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof.

15. The OLED of claim 9 wherein the anode contains the material selected from the conducting or semiconducting selenides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof.

16. The OLED of claim 9 wherein the anode contains the material selected from the conducting or semiconducting tellurides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof.

17. The OLED of claim 9 wherein the anode contains the material selected from the conducting or semiconducting nitrides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof.

18. The OLED of claim 9 wherein the anode contains the material selected from indium-tin oxide, tin oxide, aluminum-doped zinc oxide, indium-doped zinc oxide, magnesium-indium oxide, nickel-tungsten oxide, zinc sulfide, zinc selenide, or gallium nitride, or the combination thereof.

19. The tandem OLED of claim 9 wherein the anode modification layer includes a chemical compound 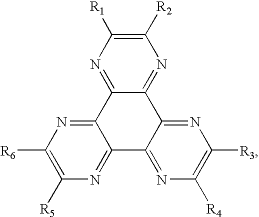
wherein R₁-R₆ represent hydrogen or a substituent independently selected from the group including halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, R₃ and R₄, or R₅ and R₆, combine form a ring structure including an aromatic ring, a heteroaromatic ring, or a non-aromatic ring, and each ring is substituted or unsubstituted.

20. The OLED of claim 9 wherein the anode modification layer includes hexanitrile hexaazatriphenylene [chemical structure]
